(19) United States
(12) Patent Application Publication
(10) Pub. No.: US 2010/0308392 A1
(43) Pub. Date: Dec. 9, 2010

(54) NONVOLATILE SEMICONDUCTOR STORAGE DEVICE

(75) Inventor: Takaaki NAGAI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/791,199

(22) Filed: Jun. 1, 2010

(30) Foreign Application Priority Data
Jun. 5, 2009 (JP) 2009-135820

(51) Int. Cl. H01L 29/788; H01L 21/336

(52) U.S. Cl. 257/315; 438/264; 257/E29.3; 257/E21.409

(57) ABSTRACT

A control gate of a nonvolatile semiconductor storage device includes a first side surface on a side near a floating gate, a second side surface opposite to the first side surface, a silicide region formed in an upper portion of the control gate above the first side surface, and a protruding portion formed in an upper portion of the control gate above the second side surface. A side wall insulating film of the nonvolatile semiconductor storage device includes a first portion which covers at least a portion of the protruding portion without covering the silicide region, and a second portion which is provided continuously from the first portion and covers the second side surface with contacting the second side surface.

### INCORPORATION BY REFERENCE

This application is based upon and claims the benefit of priority from Japanese patent application No. 2009-135820, filed on Jun. 5, 2009, the disclosure of which is incorporated herein in its entirety by reference.

### BACKGROUND OF THE INVENTION

1. Field of the Invention

The present invention relates to a nonvolatile semiconductor storage device, and in particular, a nonvolatile semiconductor storage device having a sidewall insulating film.

2. Description of Related Art

As a nonvolatile semiconductor storage device having a characteristic of being able to hold stored information even when the power is off, a nonvolatile semiconductor storage device having split gate memory cells (hereinafter referred to as a split gate nonvolatile semiconductor storage device) is known (refer to, for example, Japanese patent publication (JP-P2006-179736A)).

As described in Japanese patent publication (JP-P2006-179736A), a plurality of memory cells are arranged in the split gate nonvolatile semiconductor storage device. It is demanded to increase storage capacity without increasing an area of the split gate nonvolatile semiconductor storage device. For example, there is known a technique of reducing a size of the storage device by reducing a distance between a connecting contact and the memory cell.

In a case that the distance between the connecting contact and the memory cell is small, when misalignment occurs in forming a contact hole, a gate may contact the contact. There is known a technique of preventing short-circuit between the gate and the contact (refer to, for example, Japanese patent publication (JP-A-Heisei 11-340328)).

According to the technique described in Japanese patent publication (JP-A-Heisei 11-340328), a deposition film or an insulating film higher than a surface of a gate is formed around the gate and a side wall is provided to cover the deposition film or the insulating film. The side wall is slower in etching rate than an interlayer insulating film which covers the side wall. According to the conventional technique, even when misalignment of a contact hall occurs, the side wall remains without being etched, thereby preventing short-circuit between the gate and a contact.

The present inventor has recognized as follows.

If the technique described in Japanese patent publication (JP-A-Heisei 11-340328) is applied to the split gate nonvolatile semiconductor storage device described in Japanese patent publication (JP-P2006-179736A), a deposition film is formed on a side surface of a control gate and a side wall is formed so as to cover the deposition film.

The deposition film contains carbon. In forming the side wall insulating film, temperature of several hundreds degrees C. is applied. Therefore, in the formation of the side wall, the carbon contained in the deposition film may contaminate an insulating film forming device.

### SUMMARY

In one embodiment, a nonvolatile semiconductor storage device includes: a floating gate provided above a substrate with a gate insulating film being provided between the floating gate and the substrate; a control gate provided above the substrate such that the control gate is arranged adjacent to the floating gate with a tunnel insulating film being provided between the control gate and the floating gate; and a side wall insulating film.

Here, the control gate is preferred to include: a first side surface arranged on a side near the floating gate; a second side surface opposite to the first side surface; a silicide region formed in an upper portion of the control gate above the first side surface; and a protruding portion formed in an upper portion of the control gate arranged above the second side surface. Furthermore, the side wall insulating film includes: a first portion which covers at least a portion of the protruding portion without covering the silicide region; and a second portion which is provided continuously from the first portion and covers the second side surface with contacting the second side surface. The first portion covering the protruding portion prevents the silicide on the control gate from protruding over the side wall insulating film even if the silicide abnormally grows.

In another embodiment, a manufacturing method of a nonvolatile semiconductor storage device includes: forming on a substrate, a gate insulating film and a conductive film for floating gate in a order of the gate insulating film and the conductive film of floating gate; forming spacer insulating films each having a side wall shape on the conductive film for floating gate such that the spacer insulating films face to each other; removing the conductive film for floating gate and the gate insulating film in a region between the spacer insulating films by using the spacer insulating films as masks; forming a first diffusion layer in a surface portion of the substrate in the region between the spacer insulating films; burying a space between the spacer insulating film with conductive material after the forming the first diffusion layer; forming a floating gate by selectively removing the conductive film for floating gate outside the spacer insulating films with the spacer insulating films being used as masks; forming a tunnel insulating film which covers the floating gate, the spacer insulating films and the conductive material; forming a conductive film for control gate on the tunnel insulating film; forming a first insulating film which covers the conductive film for control gate; removing a portion of the first insulating film above the floating gate, the spacer insulating films and the conductive material such that a surface of the conductive film for control gate is partially exposed; forming a protruding portion in the conductive film for control gate by etching the conductive film for control gate such that the conductive film for control gate remains at a border between the conductive film for control gate and the first insulating film; removing the first insulating film; etching-back the conductive film for control gate to form a control gate after the removing the first insulating film while keeping a shape of the protruding portion; selectively removing the tunnel insulating film; covering the control gate with a second insulating film such that the protruding portion is covered with the second insulating film after the selectively removing the tunnel insulating film; and etching-back the second insulating film to form a side wall insulating film which covers a side surface of the control gate and the protruding portion.

The nonvolatile semiconductor storage device prevents short-circuit between the gate and a contact without forming a deposition film containing carbon.

Thus, a problem is prevented that that the carbon contained in the deposition film contaminates an insulating film forming device in the formation of a side wall.

Furthermore, in forming an LDD (Lightly Doped Drain) region, there is no interference by the deposition film. For this reason, the LDD region can be appropriately formed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a perspective view exemplifying a configuration of a split gate nonvolatile semiconductor storage device 1 according to a first embodiment;

FIG. 2 is a plan view showing the configuration of the split gate nonvolatile semiconductor storage device 1 according to the first embodiment when viewed from the top;

FIG. 3 is a sectional view exemplifying a configuration of a cross section taken along A-A′ in FIG. 2;

FIG. 4 is a sectional view exemplifying a configuration of a protruding region 8 of a control gate 14 before a control gate silicide 22 is formed;

FIG. 5 is a sectional view exemplifying a first step for manufacturing the split gate nonvolatile semiconductor storage device 1 according to the first embodiment;

FIG. 6 is a sectional view exemplifying a second step for manufacturing the split gate nonvolatile semiconductor storage device 1;

FIG. 7 is a sectional view exemplifying a third step for manufacturing the split gate nonvolatile semiconductor storage device 1;

FIG. 8 is a sectional view exemplifying a fourth step for manufacturing the split gate nonvolatile semiconductor storage device 1;

FIG. 9 is a sectional view exemplifying a fifth step for manufacturing the split gate nonvolatile semiconductor storage device 1;

FIG. 10 is a sectional view exemplifying a sixth step for manufacturing the split gate nonvolatile semiconductor storage device 1;

FIG. 11 is a sectional view exemplifying a seventh step for manufacturing the split gate nonvolatile semiconductor storage device 1;

FIG. 12 is a sectional view exemplifying an eighth step for manufacturing the split gate nonvolatile semiconductor storage device 1;

FIG. 13 is a sectional view exemplifying a ninth step for manufacturing the split gate nonvolatile semiconductor storage device 1;

FIG. 14 is a sectional view exemplifying a tenth step for manufacturing the split gate nonvolatile semiconductor storage device 1;

FIG. 15 is a sectional view exemplifying an eleventh step for manufacturing the split gate nonvolatile semiconductor storage device 1;

FIG. 16 is a sectional view exemplifying a twelfth step for manufacturing the split gate nonvolatile semiconductor storage device 1;

FIG. 17 is a sectional view exemplifying a thirteenth step for manufacturing the split gate nonvolatile semiconductor storage device 1;

FIG. 18 is a sectional view exemplifying a fourteenth step for manufacturing the split gate nonvolatile semiconductor storage device 1;

FIG. 19 is a sectional view exemplifying a fifteenth step for manufacturing the split gate nonvolatile semiconductor storage device 1;

FIG. 20 is a sectional view exemplifying a sixteenth step for manufacturing the split gate nonvolatile semiconductor storage device 1;

FIG. 21 is a plan view exemplifying the configuration of a split gate nonvolatile semiconductor storage device 1 in a comparative example;

FIG. 22 is a sectional view exemplifying the configuration of the split gate nonvolatile semiconductor storage device 1 in the comparative example;

FIG. 23 is a perspective view exemplifying the configuration of the split gate nonvolatile semiconductor storage device 1 in the comparative example;

FIG. 24 is a plan view exemplifying a configuration of a nonvolatile semiconductor storage element 101 having no protruding region 8;

FIG. 25 is a sectional view exemplifying the configuration of the nonvolatile semiconductor storage element 101;

FIG. 26 is a perspective view exemplifying the configuration of the nonvolatile semiconductor storage element 101;

FIG. 27 is a sectional view exemplifying a configuration of a split gate nonvolatile semiconductor storage device 1 according to a second embodiment;

FIG. 28 is a sectional view exemplifying a configuration of a protruding region 8 of a storage element 2 according to the second embodiment;

FIG. 29 is a sectional view exemplifying a first additional step for manufacturing the split gate nonvolatile semiconductor storage device 1 according to the second embodiment;

FIG. 30 is a sectional view exemplifying a state of the protruding region 8 in the first additional step;

FIG. 31 is a sectional view exemplifying a second additional step for manufacturing the storage element 2 according to the second embodiment;

FIG. 32 is a sectional view exemplifying a third additional step for manufacturing the storage element 2 according to the second embodiment;

FIG. 33 is a sectional view exemplifying a first modified step for manufacturing a split gate nonvolatile semiconductor storage device 1 according to a third embodiment; and

FIG. 34 is a sectional view exemplifying a second modified step for manufacturing the split gate nonvolatile semiconductor storage device 1 according to the third embodiment.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

Embodiments of the present invention will be described below based on the drawings. In the drawings for describing the embodiments, the same elements are designated by the same reference characters in principle and their repeated description is omitted.

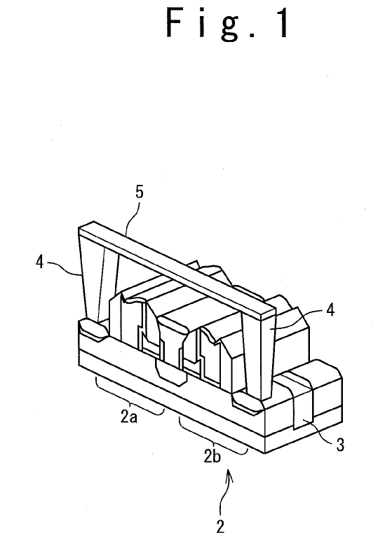

FIG. 1 is a perspective view exemplifying a configuration of a split gate nonvolatile semiconductor storage device 1 according to a first embodiment. The split gate nonvolatile semiconductor storage device 1 includes a plurality of storage elements 2 formed on a substrate. The plurality of storage elements 2 are separated by element isolation 3. The storage element 2 includes a 1-bit storage cell 2a and a 1-bit storage cell 2b. The 1-bit storage cell 2a and the 1-bit storage cell 2b are simultaneously formed to be symmetric to each other in configuration. The storage element 2 is connected to a wiring 5 through connecting contacts 4.

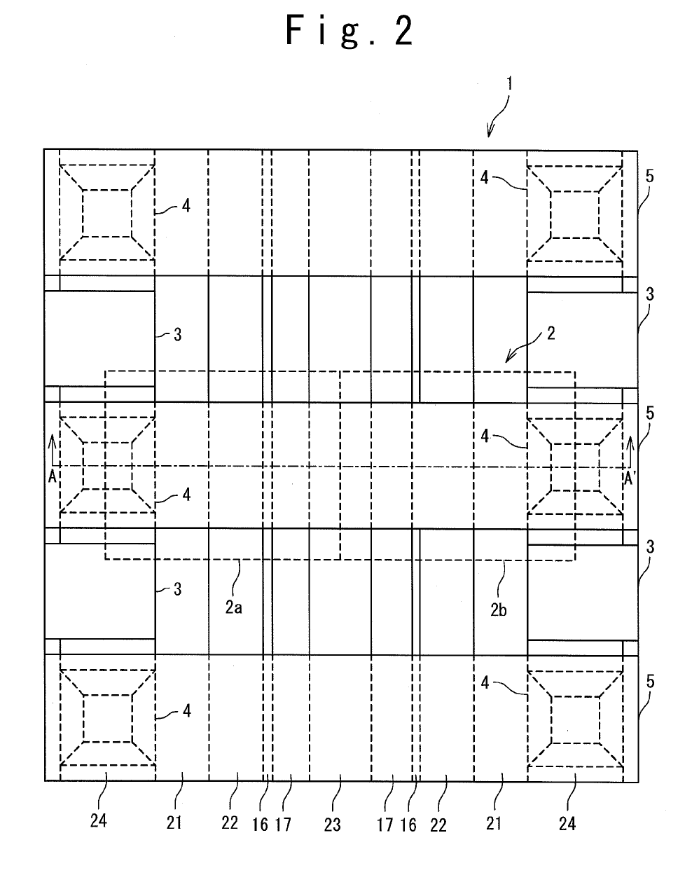

FIG. 2 is a plan view exemplifying the configuration of the split gate nonvolatile semiconductor storage device 1 according to the present embodiment when viewed from the top. In FIG. 2, in order to facilitate understanding of the split gate nonvolatile semiconductor storage device 1 according to the present embodiment, interlayer insulating films are omitted. Referring to FIG. 2, the split gate nonvolatile semiconductor storage device 1 includes the plurality of storage elements 2 separated by the element isolation 3 formed on the substrate. The storage element 2 includes the 1-bit storage cell 2a and the 1-bit storage cell 2b, and a first source/drain diffusion layer 11 (not shown in this figure) which is common to the storage cells is provided between the storage cells. The split gate nonvolatile semiconductor storage device 1 includes a source/drain diffusion layer silicide 24, a control gate side wall 21, a control gate silicide 22, a tunnel insulating film 16, a spacer insulating film 17 and a source plug silicide 23. The wiring 5 is provided in a layer above the storage elements 2. The wiring 5 is connected to the source/drain diffusion layer silicide 24 through the connecting contact 4.

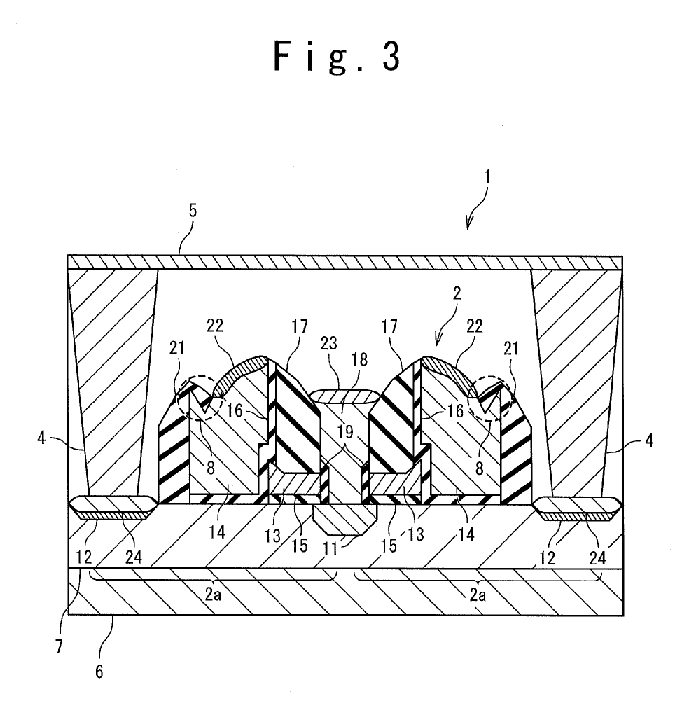

FIG. 3 is a sectional view exemplifying a configuration of a cross section taken along A-A′ in FIG. 2. As shown in FIG. 3, the storage element 2 is provided on a well 7 formed in the semiconductor substrate 6. The first source/drain diffusion layer 11 and a second source/drain diffusion layer 12 are provided in the well 7. The first source/drain diffusion layer 11 is provided in common with the 1-bit storage cell 2a and the 1-bit storage cell 2b. The source/drain diffusion layer silicide 24 is formed on the second source/drain diffusion layer 12. The source/drain diffusion layer silicide 24 is connected to the wiring 5 through the connecting contact 4.

The storage element 2 includes a floating gate 13 and a control gate 14. A gate insulating film 15 is provided between the floating gate 13 and the well 7. The tunnel insulating film 16 is provided between the control gate 14 and the well 7. The tunnel insulating film 16 is provided between the floating gate 13 and the control gate 14 such that the tunnel insulating film 16 is formed in a direction perpendicular to a plane of the well 7. The tunnel insulating film 16 is formed up to an upper portion of the control gate 14 along a side surface of the control gate 14.

The spacer insulating film 17 is provided on the floating gate 13. A source plug 18 is provided on the first source/drain diffusion layer 11 and the source plug silicide 23 is formed on the source plug 18. A floating gate side wall 19 is provided between the source plug 18 and the floating gate 13.

The control gate silicide 22 is formed on the control gate 14 of the storage element 2. The control gate side wall 21 is provided on a side surface of the control gate 14 on a side near the connecting contact 4. Here, as shown in FIG. 3, the control gate 14 includes a protruding region 8. The control gate side wall 21 is provided so as to cover an upper portion of the protruding region 8 and a side surface of the protruding region 8 on a side near the control gate silicide 22.

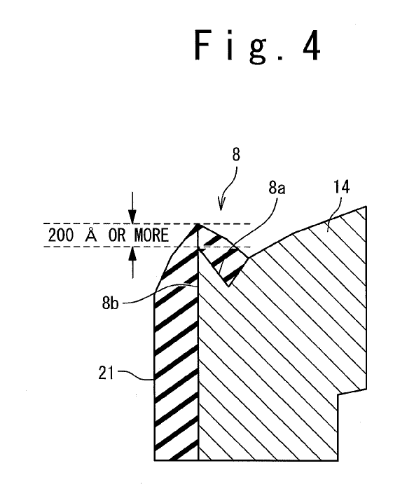

FIG. 4 is a sectional view exemplifying a configuration of the protruding region 8 of the control gate 14 before the control gate silicide 22 is formed. Referring to FIG. 4, in the storage element 2 according to the present embodiment, the protruding region 8 of the control gate 14 includes a first side surface 8a and a second side surface 8b. The control gate side wall 21 covers both of the first side surface 8a and the second side surface 8b as well as an apex of the protruding region 8. Thereby, the control gate side wall 21 according to the present embodiment prevents the control gate silicide 22 from growing beyond the control gate side wall 21 toward the connecting contact 4 when the control gate silicide 22 is formed on the control gate 14.

A manufacturing process for manufacturing the split gate nonvolatile semiconductor storage device 1 according to the present embodiment will be described below with reference to the drawings. Sectional views referred in the following description represent the position corresponding to the above-mentioned cross section taken along A-A′ in semiconductor material of the split gate nonvolatile semiconductor storage device 1 during the manufacturing process.

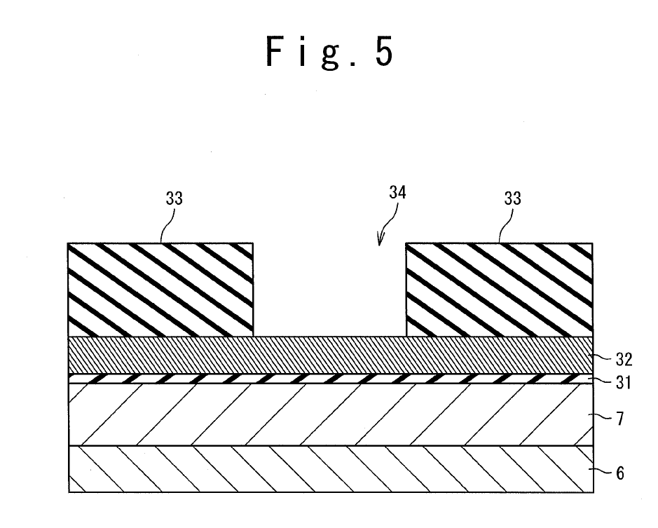

FIG. 5 is a sectional view exemplifying a first step for manufacturing the split gate nonvolatile semiconductor storage device 1 according to the present embodiment. Referring to FIG. 5, in the first step, after the well 7 is formed in the semiconductor substrate 6, a first insulating film 31 and a first polysilicon film 32 are formed on the well 7 in this order. A nitride film 33 having an opening 34 is formed on the first polysilicon film 32.

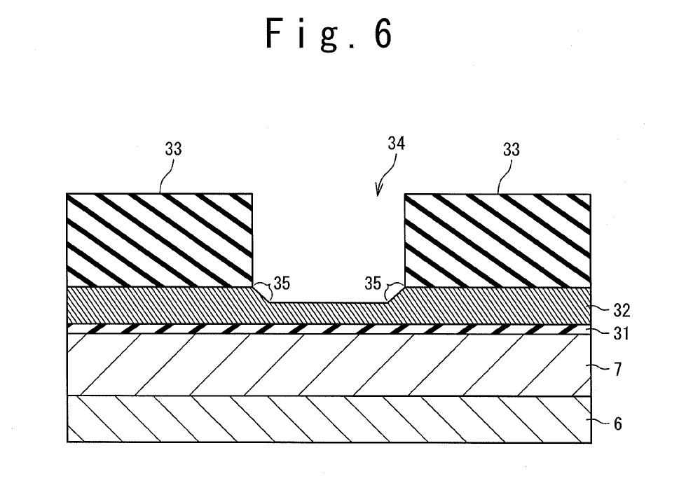

FIG. 6 is a sectional view exemplifying a second step for manufacturing the split gate nonvolatile semiconductor storage device 1. Referring to FIG. 6, in the second step, a surface of the first polysilicon film 32, which is exposed in the opening 34, is etched to form slope portions 35. The slope portion 35 is formed by etching (slope etching) in which a portion of the first polysilicon film 32 adjacent to the side surface of the nitride film 33 is obliquely shaved.

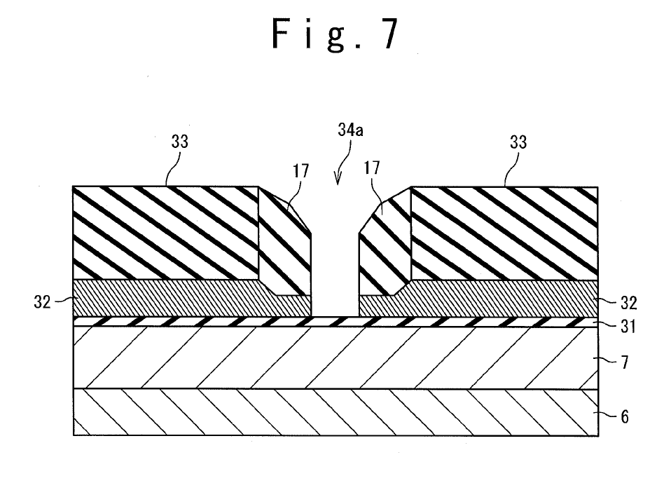

FIG. 7 is a sectional view exemplifying a third step for manufacturing the split gate nonvolatile semiconductor storage device 1. Referring to FIG. 7, in the third step, the spacer insulating films 17 are formed. The spacer insulating films 17 narrow the opening 34 to form an opening 34a. In the third step, an insulating film (for example, an oxide film) is formed to cover an upper surface and a side surface of the nitride film 33 as well as the first polysilicon film 32 exposed in the opening 34. After that, the spacer insulating films 17 are formed by etching back the insulating film. As shown in FIG. 7, the spacer insulating film 17 is formed like a side wall on the side surface of the nitride film 33. Then, in the third step, using the spacer insulating films 17 as masks, the first polysilicon film 32 is removed to expose a surface of the first insulating film 31.

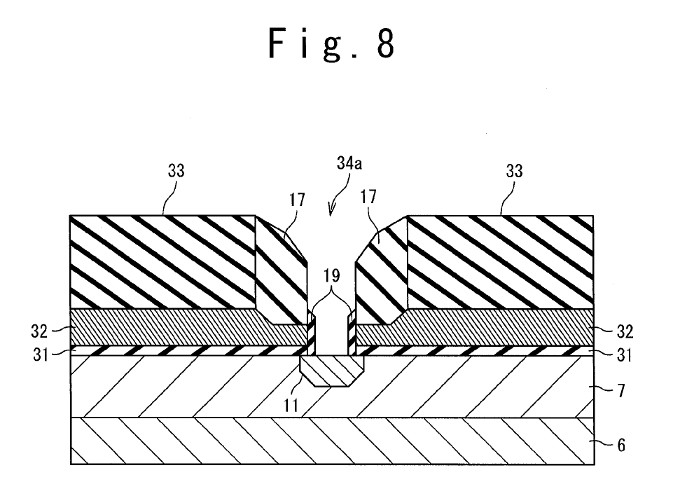

FIG. 8 is a sectional view exemplifying a fourth step for manufacturing the split gate nonvolatile semiconductor storage device 1. Referring to FIG. 8, in the fourth step, the floating gate side wall 19 and the first source/drain diffusion layer 11 are formed. In the fourth step, in order to form the floating gate side wall 19, an insulating film (for example, an oxide film) is formed to cover an upper surface of the nitride film 33, a surface of the spacer insulating film 17, a side surface of the first polysilicon film 32 and the surface of the first insulating film 31. The floating gate side wall 19 is formed by etching back the insulating film (oxide film). In this etching back, the insulating film (oxide film) and the first insulating film 31 are partially removed at the same time to expose a surface of the well 7. Then, impurities are implanted into the well 7 to form the first source/drain diffusion layer 11.

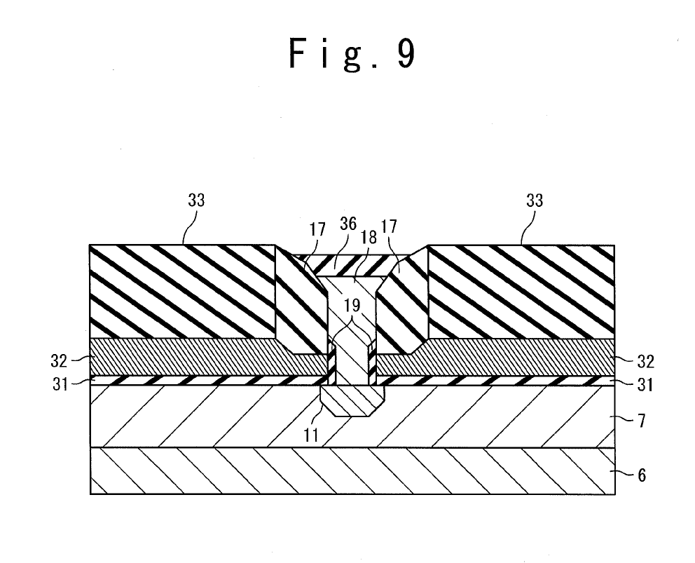

FIG. 9 is a sectional view exemplifying a fifth step for manufacturing the split gate nonvolatile semiconductor storage device 1. Referring to FIG. 9, in the fifth step, the source plug 18 and a polysilicon oxide film 36 are formed. In the fifth step, the source plug 18 is formed to bury the opening 34a. Then, the polysilicon oxide film 36 is formed as a protective film (for example, a thermal oxide film) for protecting a surface of the source plug 18.

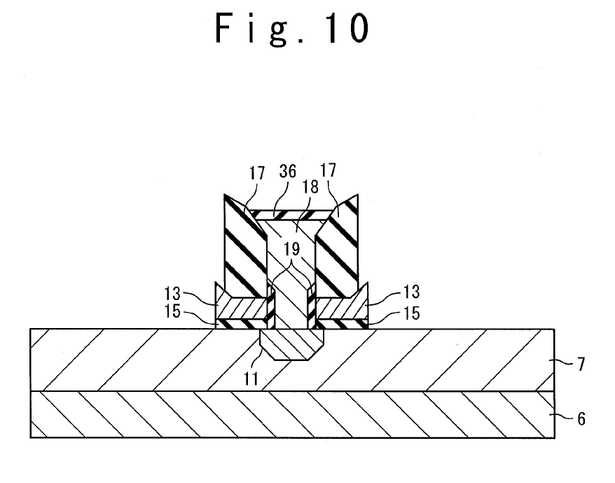

FIG. 10 is a sectional view exemplifying a sixth step for manufacturing the split gate nonvolatile semiconductor storage device 1. Referring to FIG. 10, in the sixth step, the floating gate 13 and the gate insulating film 15 are formed. In the sixth step, the nitride film 33 is removed. The removal of the nitride film 33 exposes a surface of the first polysilicon film 32. Then, etching is performed using the spacer insulating films 17 as masks to selectively remove the first polysilicon film 32 and expose a surface of the first insulating film 31. As shown in FIG. 10, an acute angled portion of the floating gate 13 is formed by this etching. Etching is performed using the spacer insulating films 17 as masks to selectively remove the first insulating film 31. By this etching, the spacer insulating films 17 are shaved by the substantially same amount as the thickness of the first insulating film 31.

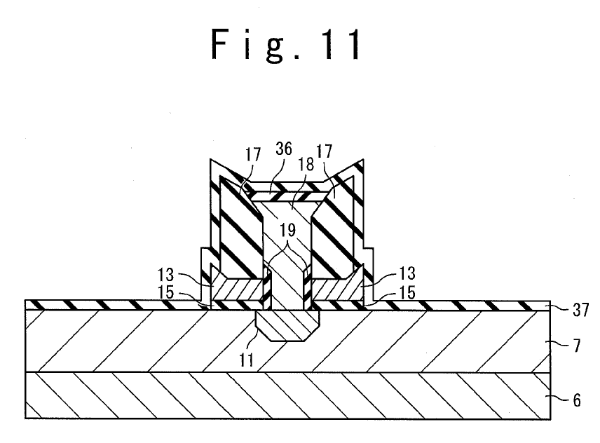

FIG. 11 is a sectional view exemplifying a seventh step for manufacturing the split gate nonvolatile semiconductor storage device 1. Referring to FIG. 11, in the seventh step, a second insulating film 37 is formed. In the seventh step, the second insulating film 37 (for example, an oxide film) is formed so as to cover an exposed surface of the well 7, a side surface of the gate insulating film 15, a side surface of the floating gate 13, a side surface and an upper surface of the spacer insulating film 17 and a surface of the polysilicon oxide film 36. The second insulating film 37 becomes the tunnel insulating film 16 in the following step.

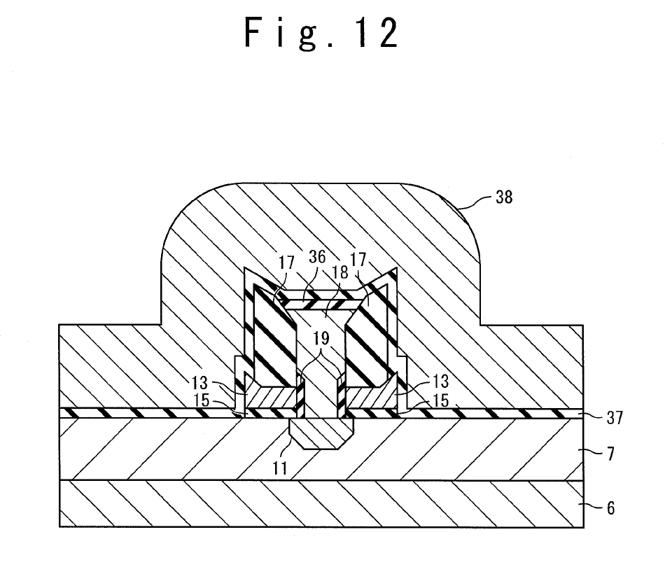

FIG. 12 is a sectional view exemplifying an eighth step for manufacturing the split gate nonvolatile semiconductor storage device 1. Referring to FIG. 12, in the eighth step, a second polysilicon film 38 is formed. In the eighth step, the second polysilicon film 38 is formed so as to cover a surface of the above-described second insulating film 37. In the present embodiment, it is preferred that the second polysilicon film 38 has a thickness of 1500 Å to 2000 Å.

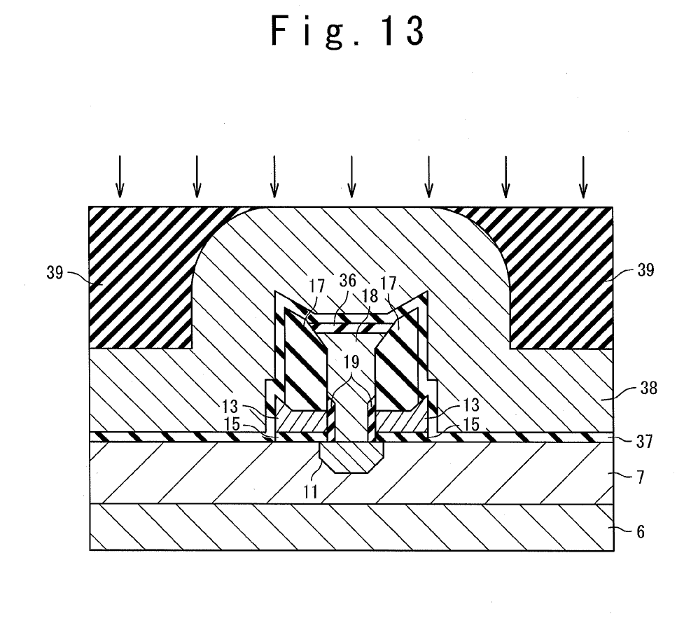

FIG. 13 is a sectional view showing a ninth step for manufacturing the split gate nonvolatile semiconductor storage device 1. Referring to FIG. 13, in the ninth step, a third insulating film 39 is formed. In the ninth step, after the third insulating film 39 (for example, a nitride film) is formed to cover an entire surface of the second polysilicon film 38, a CMP (Chemical Mechanical Polishing) is performed. The CMP is performed until an upper surface of the second polysilicon film 38 is exposed. Consequently, the level of the surface of the second polysilicon film 38 become equal to the level of the surface of the third insulating film 39.

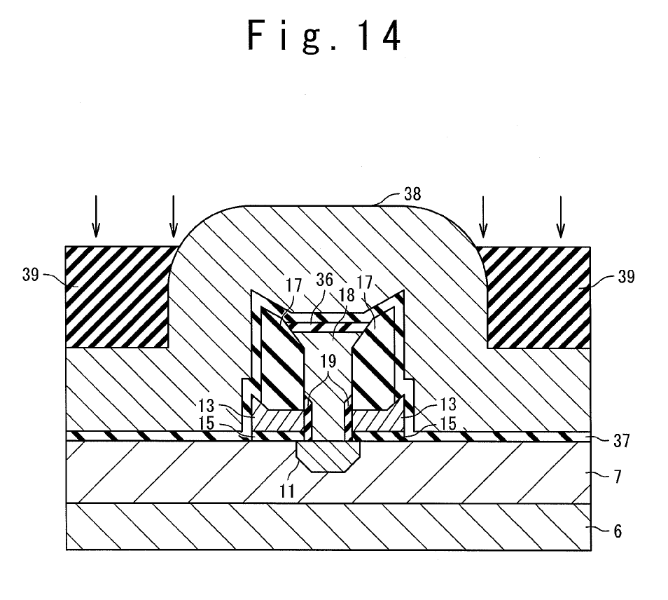

FIG. 14 is a sectional view showing a tenth step for manufacturing the split gate nonvolatile semiconductor storage device 1. Referring to FIG. 14, in the tenth step, the height of the third insulating film 39 is reduced while maintaining the second polysilicon film 38. In the tenth step, in order to form the above-mentioned protruding region 8, the third insulating film 39 is formed such that a curved portion at the shoulder of the second polysilicon film 38 is partially covered by the third insulating film 39. In the present embodiment, it is preferred that the height (film thickness) of the third insulating film 39 in the tenth step is about 1000 Å.

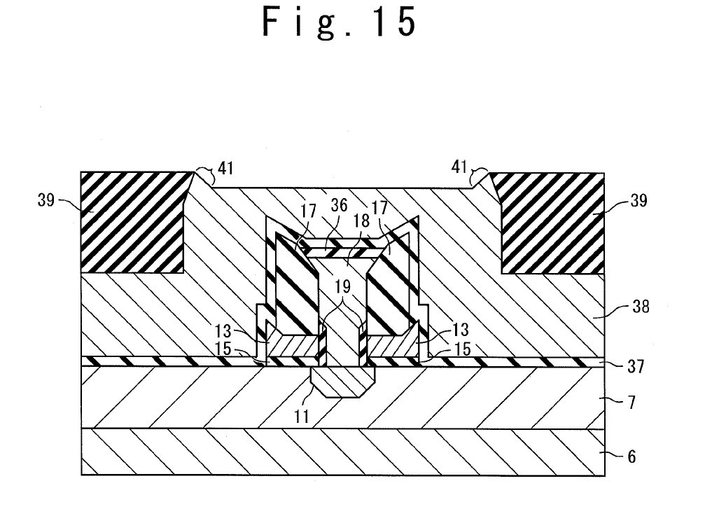

FIG. 15 is a sectional view exemplifying an eleventh step for manufacturing the split gate nonvolatile semiconductor storage device 1. Referring to FIG. 15, in the eleventh step, a slope portion 41 is formed. In the eleventh step, etching is performed using the third insulating film 39 as a mask to shave the exposed second polysilicon film 38. At this time, the slope portion 41 is formed by performing etching (slope etching) such that a slope is formed at a portion of the second polysilicon film 38 adjacent to a side surface of the third insulating film 39.

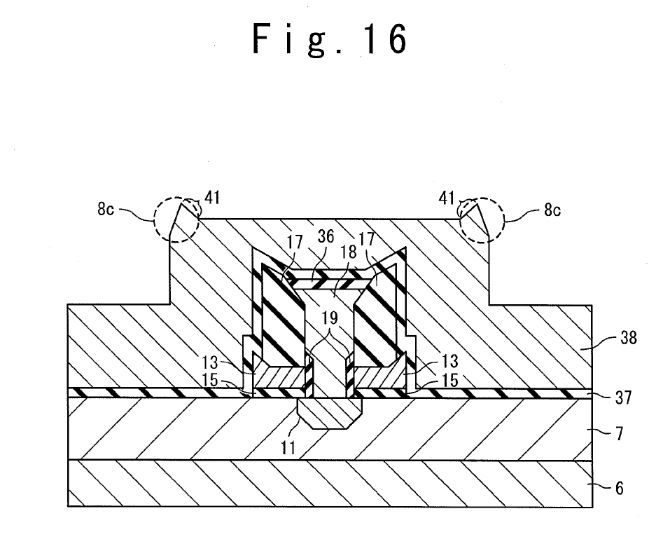

FIG. 16 is a sectional view exemplifying a twelfth step for manufacturing the split gate nonvolatile semiconductor storage device 1. Referring to FIG. 16, in the twelfth step, an initial protruding region 8c is formed. In the twelfth step, the third insulating film 39 is removed while maintaining the second polysilicon film 38. At this time, the third insulating film 39 is removed while keeping the inclination of the slope portion 41. Furthermore, the curved portion of the second polysilicon film 38, which is covered with the third insulating film 39 in the tenth step, becomes exposed. This forms the initial protruding region 8c which becomes the protruding region 8 in the following step.

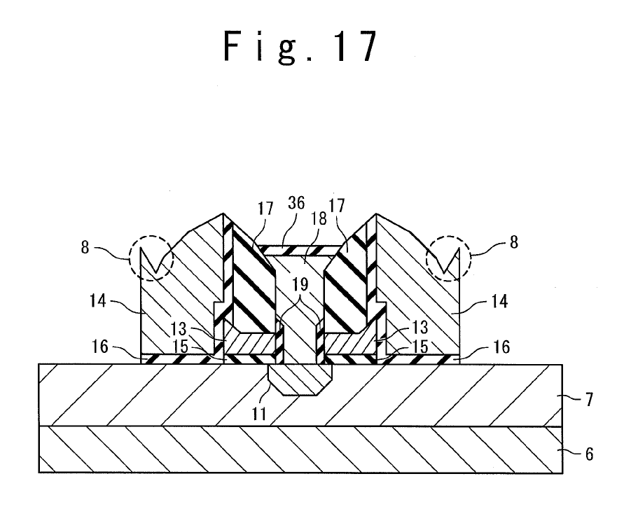

FIG. 17 is a sectional view exemplifying a thirteenth step for manufacturing the split gate nonvolatile semiconductor storage device 1. Referring to FIG. 17, in the thirteenth step, the control gate 14 and the tunnel insulating film 16 are formed. In the thirteenth step, the second polysilicon film 38 is etched back to form the control gate 14. The control gate 14 is formed so as to be in contact with the second insulating film 37 formed on side surfaces of the floating gate 13, the gate insulating film 15 and the spacer insulating film 17. In other words, the control gate 14 is formed like a side wall on the side surface of the second insulating film 37 extending in a vertical direction. At this time, the second polysilicon film 38 is removed in a region other than a region in which the control gate 14 is formed. Consequently, a surface of the second insulating film 37 is exposed in the region in which the second polysilicon film 38 is removed. Then, the exposed second insulating film 37 is removed to expose a surface of the well 7, a portion of an upper surface of the spacer insulating film 17 and a surface of the polysilicon oxide film 36. Through this process, the tunnel insulating film 16 is formed.

As shown in FIG. 17, in the thirteenth step, the protruding region 8 is formed in the control gate 14 to have a shape corresponding to a shape of the initial protruding region 8c. In other words, in the thirteenth step, a recessed portion (a valley) is formed on the upper portion of the control gate 14.

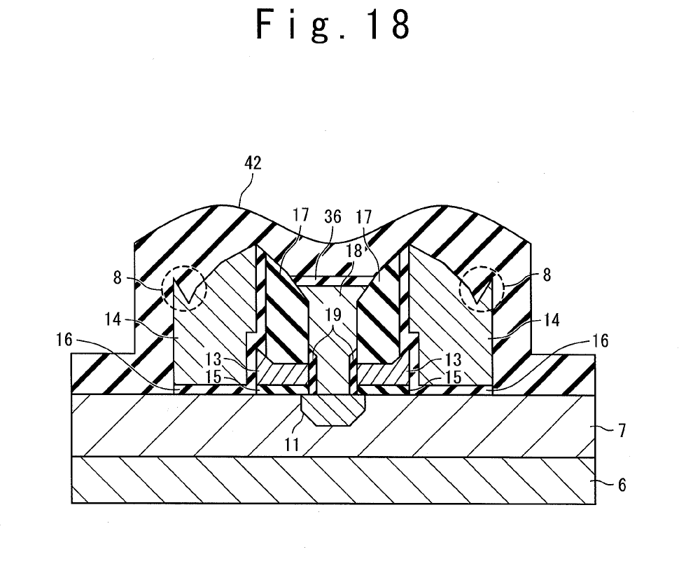

FIG. 18 is a sectional view exemplifying a fourteenth step for manufacturing the split gate nonvolatile semiconductor storage device 1. Referring to FIG. 18, in the fourteenth step, an oxide film 42 is formed. In the fourteenth step, the oxide film 42 is formed so as to cover the exposed surface of the well 7, the control gate 14, the spacer insulating film 17 and the polysilicon oxide film 36. In the present embodiment, it is preferred that the oxide film 42 has a thickness of about 1000 Å.

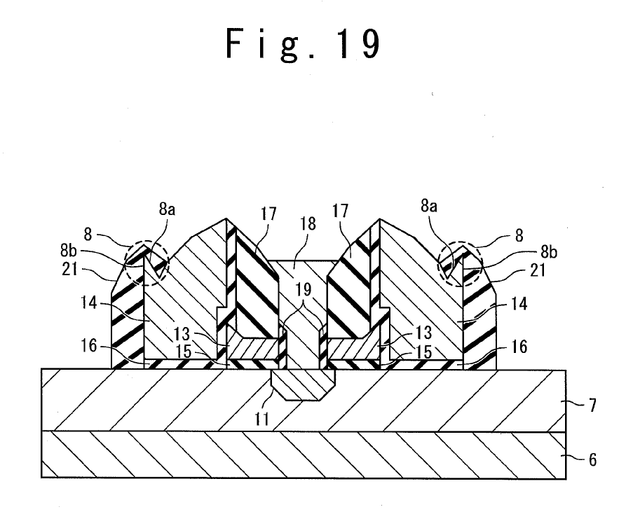

FIG. 19 is a sectional view exemplifying a fifteenth step for manufacturing the split gate nonvolatile semiconductor storage device 1. Referring to FIG. 19, in the fifteenth step, the control gate side wall 21 is formed. In the fifteenth step, the oxide film 42 is etched back to form the control gate side wall 21 on the side surface of the control gate 14. As shown in FIG. 19, the control gate side wall 21 is formed so as to cover the second side surface 8b and the first side surface 8a. In other words, the control gate side wall 21 includes a portion which functions as a side wall for the first side surface 8a and a portion which functions as a side wall for the second side surface 8b.

In the fifteenth step, the upper surface of the control gate 14 and the surface of the well 7 are partially exposed. In addition, when the oxide film 42 is etched back, the polysilicon oxide film 36 is simultaneously removed to expose a surface of the source plug 18.

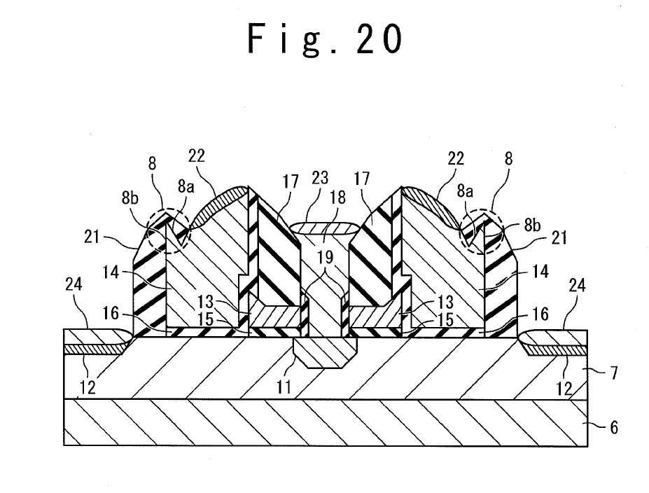

FIG. 20 is a sectional view exemplifying a sixteenth step for manufacturing the split gate nonvolatile semiconductor storage device 1. Referring to FIG. 20, in the sixteenth step, after the second source/drain diffusion layer 12 is formed, the control gate silicide 22, the source plug silicide 23 and the source/drain diffusion layer silicide 24 are formed. In the sixteenth step, impurities are implanted into the well 7 using the control gate side wall 21 as a mask to form the second source/drain diffusion layer 12. Then, surfaces of the second source/drain diffusion layer 12, the control gate 14 and the source plug 18 are silicided to form the control gate silicide 22, the source plug silicide 23 and the source/drain diffusion layer silicide 24.

As shown in FIG. 20, the control gate side wall 21 is formed so as to cover the first side surface 8a. For this reason, even if the control gate silicide 22 abnormally grows, the growth can be stopped in a vicinity of the protruding region 8.

### Comparative Example

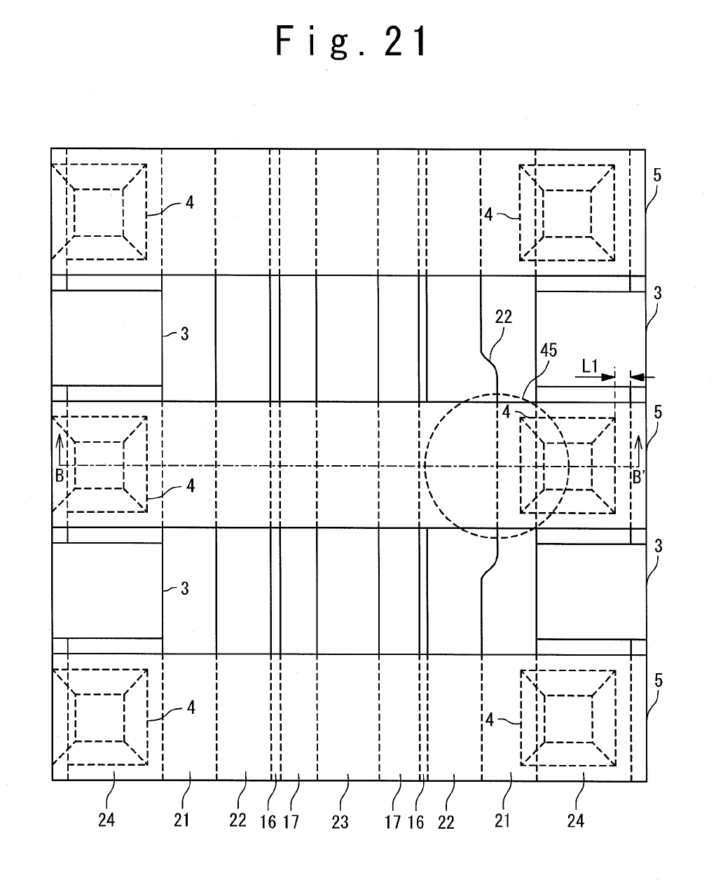

A comparative example for clarifying advantages of the split gate nonvolatile semiconductor storage device 1 according to the present embodiment will be described below. In FIGS. 21 to 26 referred in the following description, in order to facilitate understanding of the split gate nonvolatile semiconductor storage device 1 according to the present embodiment, interlayer insulating films are omitted.

FIG. 21 is a plan view exemplifying a configuration of the split gate nonvolatile semiconductor storage device 1 in the comparative example. FIG. 21 exemplifies the configuration of the split gate nonvolatile semiconductor storage device 1 when abnormal growth of the control gate silicide 22 and slight dislocations (misalignments) of forming positions of the connecting contacts 4 occur in the manufacturing process of the split gate nonvolatile semiconductor storage device 1 according to the present embodiment.

As shown in FIG. 21, the control gate silicide 22 abnormally grows toward outside in an abnormal region 45. Each of the plurality of connecting contacts 4 is formed with a dislocation from a proper position by a distance L1.

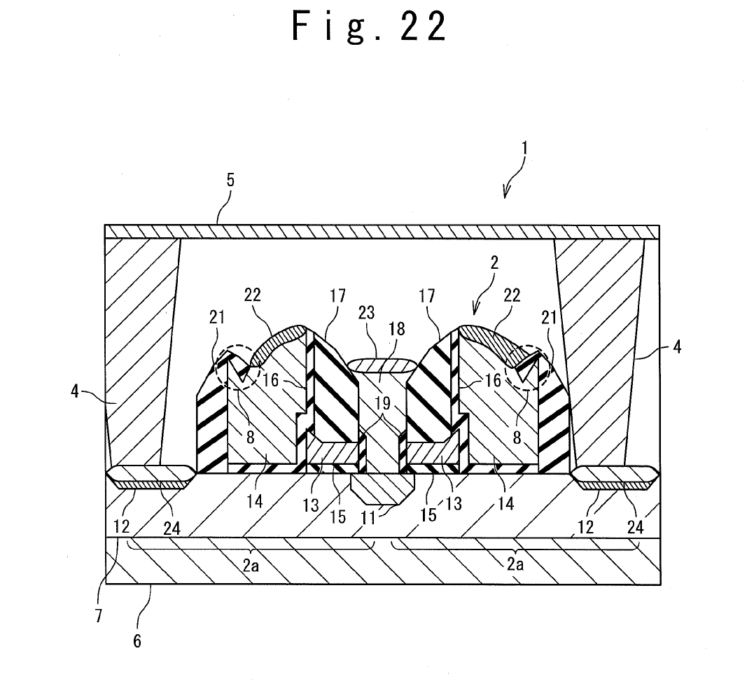

FIG. 22 is a sectional view exemplifying the configuration of the split gate nonvolatile semiconductor storage device 1 in the comparative example. FIG. 22 exemplifies a cross section taken along B-B′ in FIG. 21. Referring to FIG. 22, the control gate silicide 22 of the 1-bit storage cell 2a abnormally grows and the connecting contact 4 corresponding to the 1-bit storage cell 2a is dislocated toward the control gate side wall 21. Here, the control gate side wall 21 prevents, based on the function of the protruding region 8, the control gate silicide 22 from being formed beyond the control gate side wall 21. For this reason, a problem of short-circuit between the connecting contact 4 and the control gate silicide 22 does not occur.

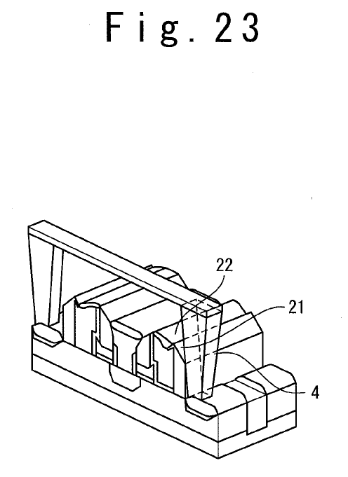

FIG. 23 is a perspective view exemplifying the configuration of the split gate nonvolatile semiconductor storage device 1 in the comparative example. A position at which the connecting contact 4 is designed to be formed has an allowable range (hereinafter referred to as a misalignment margin). When the connecting contact 4 is dislocated within the misalignment margin, no problem occurs. In the split gate nonvolatile semiconductor storage device 1 shown in FIG. 23, the connecting contact 4 is formed so as to fall within the misalignment margin. Referring to FIG. 23, the abnormal growth of the control gate silicide 22 is suppressed by the portion of the control gate side wall 21 which covers the protruding region 8. For this reason, even if a shape of the control gate silicide 22 has a problem, the connecting contact 4 can be formed without causing short-circuit between the connecting contact 4 and the control gate silicide 22.

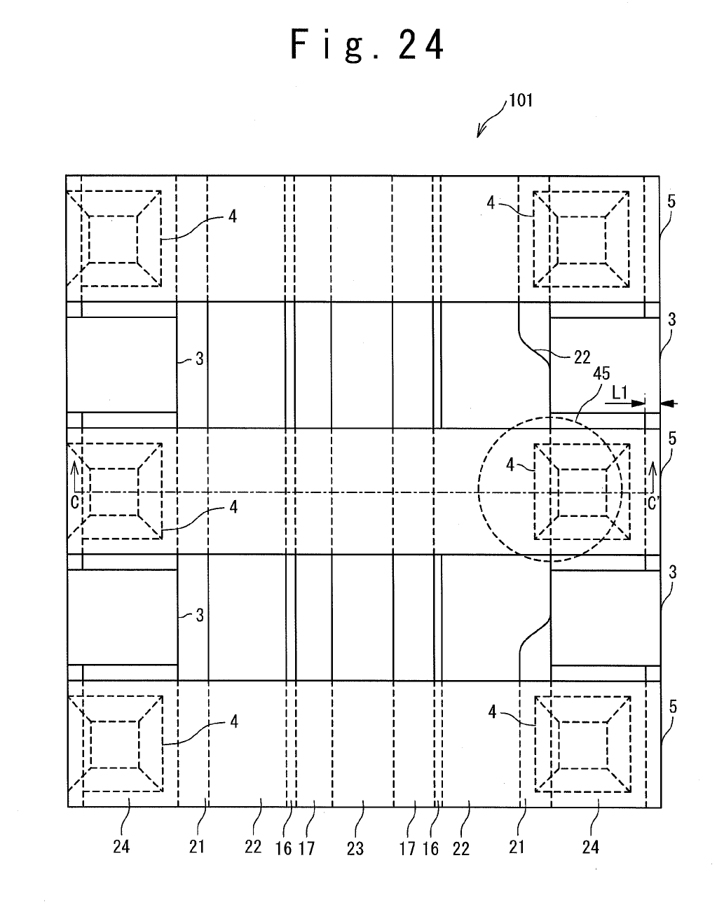

FIG. 24 is a plan view exemplifying a configuration of a nonvolatile semiconductor storage element 101 having no protruding region 8. FIG. 24 exemplifies the configuration of the nonvolatile semiconductor storage element 101 in a case that abnormal growth of the control gate silicide 22 and slight dislocations (misalignments) of the forming positions of the connecting contacts 4 occur in a manufacturing process of the nonvolatile semiconductor storage element 101.

As shown in FIG. 24, the control gate silicide 22 abnormally grows toward outside in the abnormal region 45. Each of the plurality of connecting contacts 4 is formed with a dislocation from a proper position by a distance L1.

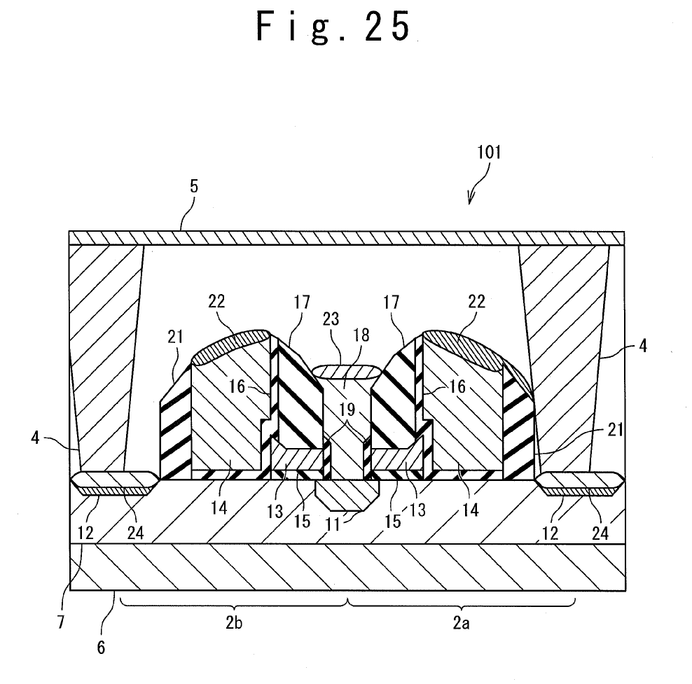

FIG. 25 is a sectional view exemplifying the configuration of the nonvolatile semiconductor storage element 101. FIG. 25 exemplifies a cross section taken along C-C′ in FIG. 24. Referring to FIG. 25, the control gate silicide 22 of the 1-bit storage cell 2a abnormally grows and the connecting contact 4 corresponding to the 1-bit storage cell 2a is dislocated toward the control gate side wall 21. At this time, the control gate silicide 22 is formed so as to exceed the control gate side wall 21 and cover the control gate side wall 21. For this reason, short-circuit between the connecting contact 4 and the control gate silicide 22 occurs in the nonvolatile semiconductor storage element 101.

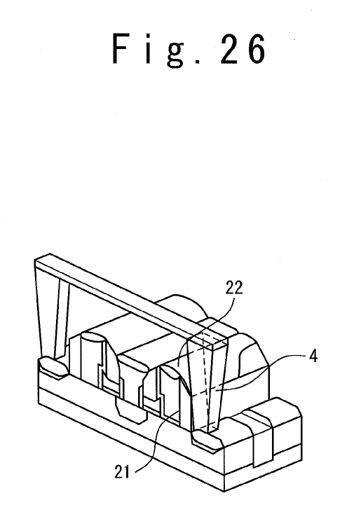

FIG. 26 is a perspective view exemplifying the configuration of the nonvolatile semiconductor storage element 101. As same in the case of the split gate nonvolatile semiconductor storage device 1, a position at which the connecting contact 4 is designed to be formed has an allowable range (hereinafter referred to as a misalignment margin). When the connecting contact 4 is dislocated within the misalignment margin, no problem occurs. In the nonvolatile semiconductor storage element 101 shown in FIG. 26, the connecting contact 4 is formed so as to fall within the misalignment margin. However, in the nonvolatile semiconductor storage element 101, the control gate silicide 22 abnormally grows to extend toward outside beyond the control gate side wall 21. For this reason, although the location of the connecting contact 4 falls within the misalignment margin, the shape of the control gate silicide 22 causes short-circuit between the connecting contact 4 and the control gate silicide 22.

As described above, the split gate nonvolatile semiconductor storage device 1 according to the present embodiment is different from the nonvolatile semiconductor storage element 101 shown in FIGS. 24 to 26 in being able to prevent short-circuit between the gate and the connecting contact while preventing a problem that a insulating film forming device is contaminated in the formation of the side wall.

According to the technique described in Japanese patent publication (JP-A-Heisei 11-340328), the thickness of STI (Shallow Trench Isolation) may be reduced in a step of removing an oxide film formed on a gate. This may result in failure of achievement of appropriate element isolation. However, the split gate nonvolatile semiconductor storage device 1 according to the present embodiment does not depend on the step of removing the oxide film formed on the gate. Thus, appropriate element isolation can be achieved.

According to the technique described in Japanese patent publication (JP-A-Heisei 11-340328), there may be interference by a deposition film in the formation of an LDD (Lightly Doped Drain) region. In the split gate nonvolatile semiconductor storage device 1 according to the present embodiment, since a deposition film is not formed, a LDD region can be appropriately formed.

### Second Embodiment

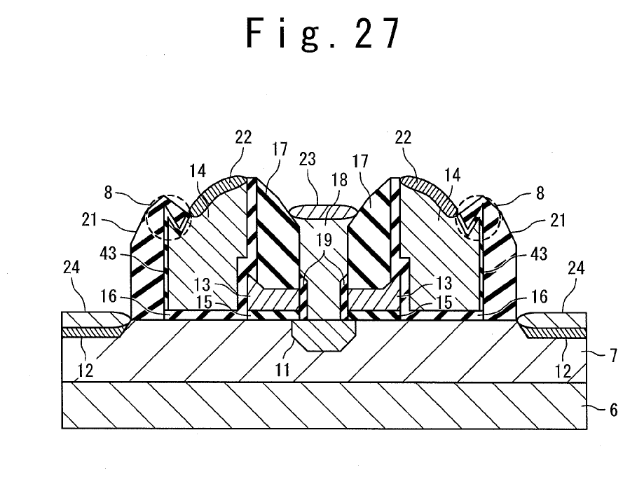

A second embodiment of the present invention will be described below referring to drawings. FIG. 27 is a sectional view exemplifying a configuration of the split gate nonvolatile semiconductor storage device 1 according to the second embodiment. As shown in FIG. 27, the split gate nonvolatile semiconductor storage device 1 according to the second embodiment includes an oxide film 43. The oxide film 43 is provided between the control gate 14 and the control gate side wall 21.

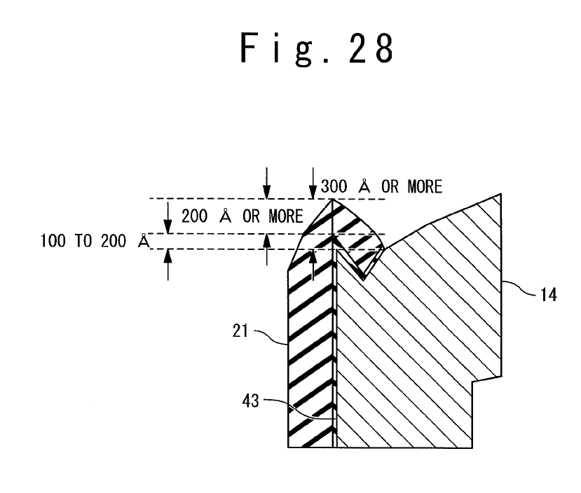

FIG. 28 is a sectional view exemplifying a configuration of the protruding region 8 of the storage element 2 according to the second embodiment. As shown in FIG. 28, the storage element 2 according to the second embodiment is formed such that the oxide film 43 has a height of 100 Å to 200 Å from an apex of the control gate 14 at the protruding region 8. The control gate side wall 21 is formed so as to have a height of about 200 Å from an apex of the oxide film 43 at the protruding region 8.

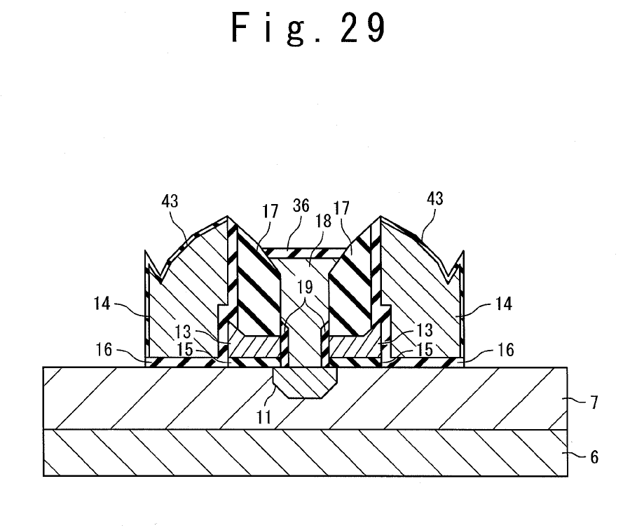

A manufacturing process for manufacturing the split gate nonvolatile semiconductor storage device 1 according to the second embodiment will be described. The split gate nonvolatile semiconductor storage device 1 according to the second embodiment is manufactured in the same manner as that of the split gate nonvolatile semiconductor storage device 1 according to the first embodiment in the first to thirteenth steps. FIG. 29 is a sectional view exemplifying a first additional step for manufacturing the split gate nonvolatile semiconductor storage device 1 according to the second embodiment. Referring to FIG. 29, in the first additional step, the oxide film 43 is formed on the exposed surface of the control gate 14. The oxide film 43 is formed, for example, by thermally oxidizing the control gate 14. Alternatively, the oxide film 43 may be formed by forming an insulating film (for example, oxide film) so as to cover the entire of the substrate and removing the insulating film so as to remain only on the surface of the control gate 14.

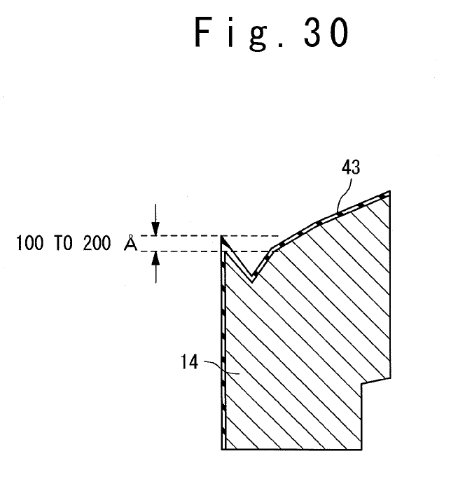

FIG. 30 is a sectional view exemplifying a state of the protruding region 8 in the first additional step. As shown in FIG. 30, the oxide film 43 is formed so as to have a height of 100 Å to 200 Å from the apex of the control gate 14 at the protruding region 8. At this time, for example, a portion of the oxide film 43 covering the side surface of the control gate 14 need not have a thickness of 100 Å to 200 Å.

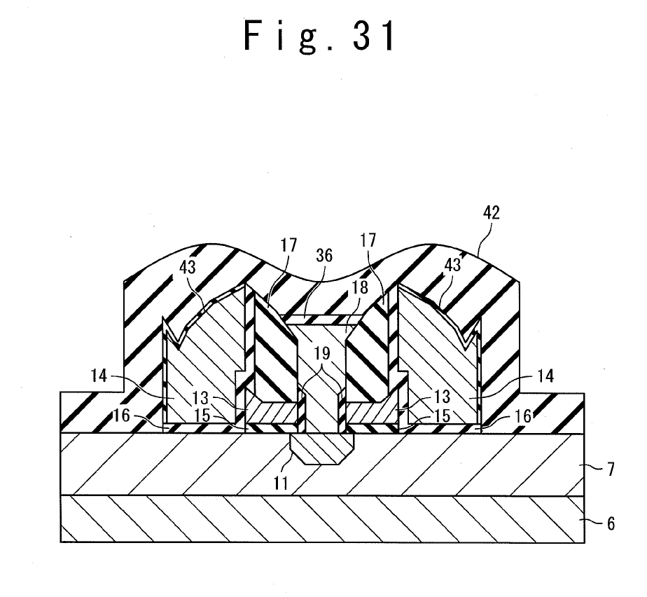

FIG. 31 is a sectional view exemplifying a second additional step for manufacturing the storage element 2 according to the second embodiment. Referring to FIG. 31, in the second additional step, the oxide film 42 is formed to cover the oxide film 43. In the second additional step, the oxide film 42 is formed so as to cover the exposed surface of the well 7, the oxide film 43, the spacer insulating film 17 and the polysilicon oxide film 36. In the present embodiment, it is preferred that the oxide film 42 has a thickness of about 1000 Å.

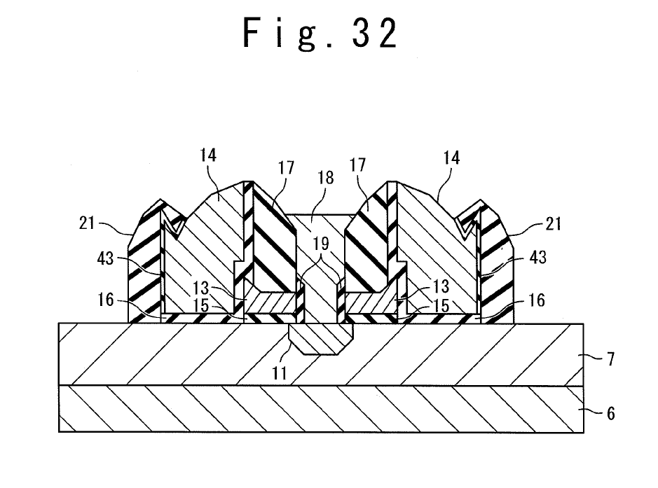

FIG. 32 is a sectional view exemplifying a third additional step for manufacturing the storage element 2 according to the second embodiment. Referring to FIG. 32, in the third additional step, the control gate side wall 21 is constituted so as to cover the oxide film 43. In the third additional step, the above-described oxide film 42 is etched back to form the control gate side wall 21 which covers the side surface of the control gate 14 through the oxide film 43. As same in the first embodiment, the control gate side wall 21 of the storage element 2 according to the second embodiment is formed so as to cover the second side surface 8b and the first side surface 8a. Thereafter, the same steps as in the first embodiment are performed to manufacture the split gate nonvolatile semiconductor storage device 1 according to the second embodiment.

Even if the etching for forming the control gate side wall 21 is inadequately performed in the third additional step such that the oxide film 42 is excessively removed, the storage element 2 according to the second embodiment can prevent, based on the function of the oxide film 43, the control gate 14 from being exposed.

### Third Embodiment

A manufacturing process for manufacturing a split gate nonvolatile semiconductor storage device 1 according to a third embodiment will be described below referring to drawings. The manufacturing process for manufacturing the split gate nonvolatile semiconductor storage device 1 according to the third embodiment is different in the step of manufacturing the initial protruding region 8c from that in the first embodiment or the second embodiment. The split gate nonvolatile semiconductor storage device 1 according to the third embodiment is manufactured in the same manner as that in the first embodiment in the first to ninth steps.

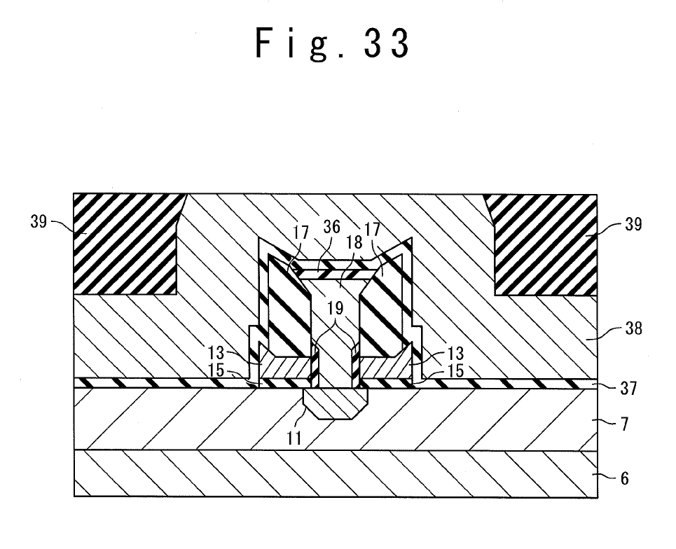

FIG. 33 is a sectional view exemplifying a first modified step in the manufacturing process of the split gate nonvolatile semiconductor storage device 1 according to the third embodiment. In the first modified step, after the third insulating film 39 is formed, a planarization using CMP or the like is performed such that a level of the surface of the second polysilicon film 38 becomes equal to a level of the surface of the third insulating film 39.

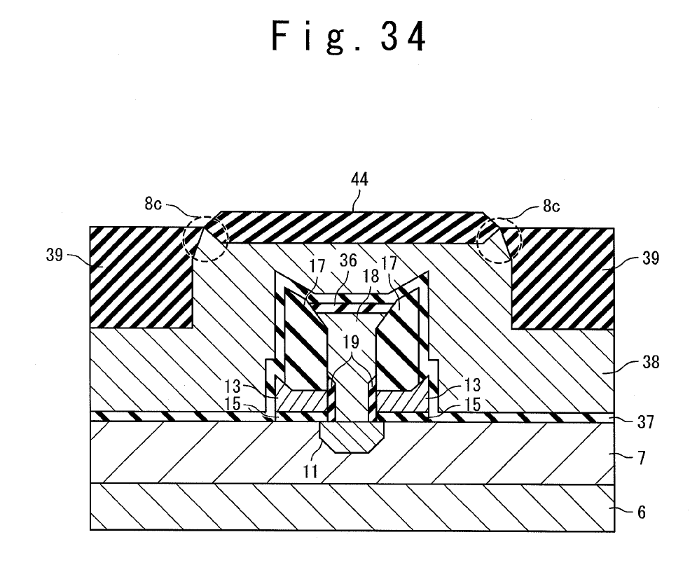

FIG. 34 is a sectional view exemplifying a second modified step in the manufacturing process of the split gate nonvolatile semiconductor storage device 1 according to the third embodiment. In the second modified step, an oxide film 44 is formed by thermally oxidizing the exposed surface of the second polysilicon film 38. The oxide film 44 is removed in the following step to form the initial protruding region 8c.

The embodiments of the present invention have been specifically described. However, the present invention is not limited to the above embodiments, but may be modified and changed without departing from the scope and spirit of the invention. Furthermore, the plurality of above embodiments may be combined so as not to cause contradiction in configuration and operation.

What is claimed is:

1. A nonvolatile semiconductor storage device comprising:
a floating gate provided above a substrate with a gate insulating film being provided between said floating gate and said substrate;
a control gate provided above said substrate such that said control gate is arranged adjacent to said floating gate with a tunnel insulating film being provided between said control gate and said floating gate; and
a side wall insulating film,
wherein said control gate includes:
a first side surface on a side near said floating gate;
a second side surface opposite to said first side surface;
a silicide region formed in an upper portion of said control gate above said first side surface; and
a protruding portion formed in an upper portion of said control gate above said second side surface, and
said side wall insulating film includes:
a first portion which covers at least a portion of said protruding portion without covering said silicide region; and
a second portion which is provided continuously from said first portion and covers said second side surface with contacting said second side surface.

2. The nonvolatile semiconductor storage device according to claim 1, wherein said protruding portion includes:
a first region formed as a side surface on a side near said floating gate; and
a second region opposite to said first region and formed as a surface continued from said second side surface,
said first portion of said side wall insulating film covers said first region, and
said second portion of said side wall insulating film covers said second region and said second side surface.

3. The nonvolatile semiconductor storage device according to claim 2, wherein a cross-section of said protruding portion includes:
a first edge corresponding to said first region;
a second edge corresponding to said second region; and
an apex between said first edge and said second age,
said cross-section is included in a cutting plane perpendicular to said substrate and said first side surface, and
said side wall insulating film covers said apex.

4. The nonvolatile semiconductor storage device according to claim 3, said side wall insulating film includes a first end corresponding to a position at which a surface of said first portion intersects a upper surface of said control gate, and
said silicide region is provided on said upper surface from said first end to said first side surface.

5. The nonvolatile semiconductor storage device according to claim 4, said side wall insulating film includes a second end corresponding to a position at which a surface of said second portion intersects a surface of said substrate, and
said side wall insulating film is formed from said first end to said second end with covering said first edge and said second edge.

6. A manufacturing method of a nonvolatile semiconductor storage device comprising:
forming on a substrate, a gate insulating film and a conductive film for floating gate in a order of said gate insulating film and said conductive film of floating gate;
forming spacer insulating films each having a side wall shape on said conductive film for floating gate such that said spacer insulating films face to each other;
removing said conductive film for floating gate and said gate insulating film in a region between said spacer insulating films by using said spacer insulating films as masks;
forming a first diffusion layer in a surface portion of said substrate in said region between said spacer insulating films;
burying a space between said spacer insulating film with conductive material after said forming said first diffusion layer;
forming a floating gate by selectively removing said conductive film for floating gate outside said spacer insulating films with said spacer insulating films being used as masks;
forming a tunnel insulating film which covers said floating gate, said spacer insulating films and said conductive material;
forming a conductive film for control gate on said tunnel insulating film;
forming a first insulating film which covers said conductive film for control gate;
removing a portion of said first insulating film above said floating gate, said spacer insulating films and said conductive material such that a surface of said conductive film for control gate is partially exposed;
forming a protruding portion in said conductive film for control gate by etching said conductive film for control gate such that said conductive film for control gate remains at a border between said conductive film for control gate and said first insulating film;
removing said first insulating film;
etching-back said conductive film for control gate to form a control gate after said removing said first insulating film while keeping a shape of said protruding portion;
selectively removing said tunnel insulating film;
covering said control gate with a second insulating film such that said protruding portion is covered with said second insulating film after said selectively removing said tunnel insulating film; and
etching-back said second insulating film to form a side wall insulating film which covers a side surface of said control gate and said protruding portion.

7. The manufacturing method of a nonvolatile semiconductor storage device according to claim 6, further comprising:
implanting impurities into a region of said substrate arranged outside said spacer insulating films to form a second diffusion layer, and
forming silicide on a surface of said conductive material between said spacer insulating films, a surface of said control gate and a surface of said second diffusion layer.

8. The manufacturing method of a nonvolatile semiconductor storage device according to claim 6, wherein said forming said protruding portion includes performing a slope etching to form a slope in said border between said conductive film for control gate and said first insulating film, and
said performing said slope etching includes forming an apex of said protruding portion to be acute-angled.

9. The manufacturing method of a nonvolatile semiconductor storage device according to claim 6, wherein said etching-back said conductive film for control gate includes forming a valley in an upper portion of said control gate by etching-back said conductive film for control gate.
